(19) United States
(12) Patent Application Publication
(10) Pub. No.: US 2017/0233597 A1
(43) Pub. Date: Aug. 17, 2017

(54) METHOD OF FABRICATING HIGH-PERFORMANCE POLY (VINYLIDENEDIFLUORIDE-TRIFLUOROETHYLENE), P(VDF-TRFE) FILMS

(71) Applicant: INDIAN INSTITUTE OF TECHNOLOGY, KANPUR, Kanpur (IN)

(72) Inventors: Deepa SINGH, Kanpur (IN); Deepak GUPTA, Kanpur (IN); Ashish GARG, Kanpur (IN)

(21) Appl. No.: 15/198,703

(22) Filed: Jun. 30, 2016

(30) Foreign Application Priority Data
Feb. 16, 2016 (IN) 201611005439

(51) Int. Cl. C09D 127/16; H01L 27/20; B05D 3/00; H01L 27/115; B05D 1/00; B05D 3/06

(52) U.S. Cl. CPC C09D 127/16; B05D 1/005; B05D 3/061; B05D 3/007; H01L 27/11502; H01L 27/20; B05D 2203/30; B05D 2507/015

(57) ABSTRACT

The present invention relates to a process of fabricating P(VDF-TrFE) films by modifying the solvent composition. Two solvents MEK and DMSO were mixed in pre-determined ratios and that co-solvent mixture was used for fabricating the P(VDF-TrFE) films. By virtue of such method driven P(VDF-TrFE) films, the ferroelectric capacitors comprising of the same were found to achieve low voltage operation, thermal stability and fatigue endurance, which indicated improved ferroelectric performance of the devices. In addition, the films made by same process also yielded high piezo- and pyro-electric coefficient, indicating improved piezo- and pyro-electric performances of the devices.

### FIELD OF INVENTION

The present invention relates to a method for fabricating organic thin film ferroelectric materials having improved fatigue and thermal stability for use in nonvolatile memory applications. The applications can also extend to piezoelectric and pyroelectric devices such as sensors and detectors. The materials include a fluoropolymer in a defined solvent blend that allows for the improved characteristics.

### BACKGROUND OF THE INVENTION AND PRIOR ART

Non-volatile memory (NVM) is a form of electronic memory used for long term persistent storage of data whose contents are saved even when the external power source is turned off. NVMs are used in a wide variety of commercial and military electronic devices and equipment, such as hand-held telephones, flash memory devices, hard disk drives, optical drives, radios, digital cameras etc. The important characteristics for a non-volatile memory cell in electronic device are low cost, high bitdensity, low power consumption, high speed operation and high electrical fatigue endurance.

In recent years, NVMs and NVM mediated devices based on organic materials as the memory substance, in particular ferroelectric polymers, have been proposed and demonstrated. Of particular interest in the present context are those that can be built on flexible substrates and that well adapt themselves to simple and high volume manufacturing processes. For such organic memory devices with additional benefit for flexibility, one of the most promising material is the ferroelectric polymer poly (vinylidenedifluoride-trifluoroethylene), abbreviated as P(VDF-TrFE). Among various bottlenecks in commercialization of this ferroelectric polymer, two important ones are high power consumption (or high voltage operation) and low fatigue endurance. Whilst, lower voltage operation in the devices can be achieved by using thinner films, use of very thin film can often lead to defects and short-circuiting in the memory devices.

In recent past, there have been some successful works done in achieving low power consumption in P(VDF-TrFE) based capacitors. For example, R. C. G. Naber et. al. [Appl. Phys. Lett. 87, 203509 (2005)] and G. Knotts et. al. [Appl. Phys. Lett. 104, 233301 (2014)] have demonstrated that by depositing films using a higher dipole moment solvent such as cyclohexanone and dimethyl sulfoxide (DMSO) low voltage operating devices can be achieved. But none of the above reports provides the effect of these solvents on the breakdown strength and fatigue/retention endurance.

M. A. Khan et al.: Adv. Funct. Mater., 24, 1372 (2014) discloses high-performance polymer memory which is fabricated using blends of ferroelectric poly(vinylidenefluoride-trifluoroethylene) (P(VDF-TrFE)) and highly insulating poly(p-phenylene oxide) (PPO) along with enhanced thermal stability, excellent fatigue endurance (80% retention after 10⁶ cycles at 1 KHz) and high dielectric breakdown fields (≈360 MV/m).

Similarly, WO2014/158956 relates to ferroelectric polymer based capacitor with improved fatigue and breakdown properties, wherein enhanced thermal stability (˜353K), fatigue endurance (80% retention after 10⁶ cycles at 1 KHz) and high dielectric breakdown fields (≈360 MV/m) were achieved by adding an insulating material poly(p-phenylene oxide) (PPO).

However, addition of PPO reduces the polarization as well as dielectric constant and switching current, which is not preferable. Thus, a gate dielectric with high permittivity is needed in order to reduce the operating voltage of organic thin film transistors effectively without the need for thickness reduction. Hence reduction in dielectric constant and polarization should be avoided. In addition, for commercial application, the fatigue endurance of P(VDF-TrFE) thin film capacitors is still very low which should ideally be greater than 10¹⁰ number of bipolar switching cycles.

On the other hand, D. Zhao et al.: Scientific reports, 4, 5075 (2014) reveals that a fatigue-free capacitor can be realized by using a polymer electrode (PEDOT:PSS) and a triangular waveform with waiting time of 10 seconds.

But, the properties of P(VDF-TrFE) is very much affected by using electrodes such as PEDOT:PSS electrode which is not covalently bound to the polymer layer. The adhesion between the polymer layer and the electrode is limited to van der Waals forces. This could lead to improved fatigue properties but reduction in polarization.

Many other strategies have been reported in the art to overcome the common problems with ferroelectric polymers such as occurrence of high level of chemical defects resulting in a low degree of crystallinity and consequently a low polarization potential. This has also a negative effect on the switching and fatigue behaviour. The switching may for instance become slower and require a very high field voltage. For instance, in EP1423856 B1, such problems of chemical defects of ferroelectric polymers were reduced by introducing a deuterated polymer. The introduction of a deuterated polymer is a complex process. Furthermore, U.S. Pat. No. 6,423,412B1 discloses that the relaxor properties of the ferroelectric polymer for high energy storage was achieved by electron beam radiation in P(VDF-TrFE) which eliminated the ferroelectric hysteresis. Such electron beam curing of polymers is a complex process incurring high equipment cost and human expertise. US20070003695A1 further discloses a process of melt quenched ferroelectric films, wherein crystallinity and Curie temperature of the films is increased by rapidly cooling the polymer from an elevated temperature (greater than melting point of the polymer) which in turn expands the operating range of a ferroelectric polymer.

US20090294817A1 (in short US'817) relates to ferroelectric memory device comprising a ferroelectric organic polymer and an oxidiser and/or deionizer. US'817 also discloses that due to the alternating electric field, electrons are injected into the P(VDF/TrFE) layer which ionises the Fluorine to generate free F⁻ ions. These free F⁻ ions then react with the migrated Al³⁺ ion at the interface between the P(VDF/TrFE) layer and the Al electrode. The AlF₃ thus produced affects the ferroelectric and fatigue properties. In US'817, this problem has been overcome by introducing 4-vinylpyridine (4VP) monomer into the ferroelectric polymer as an oxidiser and/or deionizer which provides improved fatigue endurance by reacting with free fluorine ions in the ferroelectric polymer. This is a complex process and involves many reactive ingredients.

U.S. Pat. No. 4,728,844A relates to a piezoelectric transducer comprising of P(VDF-TrFE) containing nickel and bismuth oxide each in particulate form. This is also a complex process involving many reactive ingredients.

Further, U.S. Pat. No. 7,955,641B2 (in short US'641) discloses a method of forming a piezoelectric device, wherein P(VDF-TrFE) is used as a coating material and methyl ethyl ketone as a liquid carrier. In US'641, P(VDF-TrFE) is heated to a temperature that is above the Curie temperature but below the melting temperature. Along with the temperature an electric field is applied to the P(VDF-TrFE) films in order to pole the crystals that are formed. This even involves a complex process wherein the P(VDF-TrFE) film is subjected to both heat and voltage to obtain piezoelectric properties.

Additionally, Rubaiyet Iftekharul Haque et al.: Flex. Print. Electron. 1 (2016) 015001 discloses inkjet-printed polymer layers obtained with DMSO/MEK (80/20 wt. %) for different concentrations of PVDF-TrFE polymer. It also discloses that best jettability and suited surface tension of the polymer based ink was observed due to the solution mixture of DMSO and MEK. This particular solvent composition has low viscosity that permits the fabrication of stable PVDF-TrFE ink with 0.8 wt. % high molecular weight polymer content. MEK has lower density than DMSO and is highly volatile which can cause the cartridge clogging. So the authors mixed MEK with DMSO having high boiling point and low vapour pressure. Also, the ink in MEK alone exhibits tail formation of droplets that does not separate from the nozzle. Whilst by mixing DMSO and MEK the authors showed successful printing of P(VDF-TrFE) film, there is no mention of any detail on ferroelectric properties of printed P(VDF-TrFE) film. However, the prior art does not show any improvement of ferro-, piezo- and pyro-electric properties.

Thus the methods of fabricating P(VDF-TrFE) film as mentioned in the above prior arts suffers from the following drawbacks, that when measures are taken to improve fatigue properties:
(1) the other ferroelectric properties such as polarization and dielectric constant deteriorate.
(2) most prior arts reportedly used an additive that requires an additional fabrication step.
(3) polymer electrode is used to replace conventional metal electrodes but such polymer electrodes were found to be environmentally unstable and hence can't be used for long time.

Further references are made to prior arts that reports P(VDF-TrFE) films that shows piezoelectric properties.

Hong-Jie Tseng et. al: Sensors, 13 (11) (2013) discloses that deionized (DI) water dissociation was used to treat and change the contact angle of the surface of stainless steel substrates followed by the spin coating of P(VDF-TrFE) material for the fabrication of tactile sensors. The piezoelectric co-efficient (d₃₃) value achieved by this process was found to be approximately −10.7 pC/N for the substrate treated at 0 V and reached a minimum of −5 pC/N for treatment at −60 V.

A. V. Bune et. al: Journal of Applied Physics, 85, number 11, 7869 (1999) discloses that the piezoelectric and pyroelectric responses of ferroelectric Langmuir-Blodgett (LB) polymer films are less than the largest values measured with bulk films of the same composition. The d33 value of such LB polymers was found to be −20±2 pm/V.

Yoon-young Choi et. al.: Scientific Reports, Article no. 10728 (2015) discloses vertically aligned P(VDF-TrFE) core-shell structures using high modulus polyurethane acrylate (PUA) pillars as the support structure to maintain the structural integrity. Improve piezoelectric effect was observed by 1.85 times from 40±2 to 74±2 pm/V when compared to the thin film counterpart, which contributes to the more efficient current generation under a given stress, by making an effective use of the P(VDF-TrFE) thin top layer as well as the side walls.

Rachid Hazi et. al, IEEE transactions on ultrasonics, ferroelectrics, and frequency control, 59(1), 163-7. (2012) discloses that alumina nanoparticles were dispersed in the copolymer P(VDF-TrFE) which exhibits high piezoelectric coefficient after polarization under high electric field without needing stretching during the polarization process. The d₃₃ value was reported to be 22 pm/V.

The commercially available P(VDF-TrFE) copolymer in ratio 70/30 with film thickness of 20 μm (±10%) from Piezotech S.A.S. Arkema France is reported to have a d₃₃ value of −20±10% pm/V.

However, thicker free standing P(VDF-TrFE) films of the present invention achieves the best piezoelectric performance reported in the art till date.

Further references are made to prior art that reports P(VDF-TrFE) films showing pyroelectric properties.

Bowen C. R. et al.: Energy Environ. Sci., 7, 3836 (2014) discloses that since the pyroelectric effect originates from spontaneous polarisation within the material, all pyroelectric materials are also piezo-electric, therefore hybrid pyro-piezo harvesting systems are of interest. In the design of such systems care must be taken to ensure both harvesting mechanisms are working in phase to enhance power generation. The new systems that use thermal fluctuations or thermal gradients to generate a mechanical stress to enhance the secondary or tertiary pyroelectric coefficients are also of interest. This review article further discloses that pyroelectric co-efficient (p) of a material is defined as p=dPs/dT at constant electric field and stress. However, pyroelectric performance known in the art is still not satisfactory.

Therefore, there still remains a need in the art to develop a simple and cost-effective process to fabricate P(VDF-TrFE) based memory capacitors with low voltage operation and higher fatigue endurance with better polarization values.

Accordingly, the present invention provides a process of fabricating thin films of P(VDF-TrFE) by simply modifying the solvent composition. Advantageously, the present process does not involve any cumbersome process or does not need changing the electrode or adding of any other interfaces making the process cost efficient and simple. The present process can be employed in making non-volatile memory integrated devices. In the ferroelectric capacitors prepared by the present process, the inventors are able to achieve low voltage operation and fatigue endurance, which indicates improved performance of the memory devices. Furthermore, in the present invention, an improved fatigue endurance with low operating voltage devices were achieved, but without modifying the electrode structure as such or varying the P(VDF-TrFE) film thickness.

### OBJECTS OF THE INVENTION

An object of the invention is to overcome the disadvantages of the prior art.

Another object of the present invention is to provide a simple and cost-effective process for fabricating ferroelectric polymers such as P(VDF-TrFE) films.

Another objective of the present invention is to provide a process for fabricating P(VDF-TrFE) films that possesses improved fatigue endurance and thermal stability.

Another objective of the present invention is to provide a process of fabricating P(VDF-TrFE) films that possesses improved crystallinity and favourable molecular alignment and possibly low level of defects.

Another object of the present invention is to provide a method of fabricating P(VDF-TrFE) films by using specific compositions of solvent mixture of methyl ethyl ketone (MEK) and dimethyl sulfoxide (DMSO) which allows for improved crystallographic alignment of the P(VDF-TrFE) film on a substrate from the perspective of polar axis and also leads to excellent electrical fatigue endurance of P(VDF-TrFE).

Another objective of the present invention is to fabricate a fatigue free P(VDF-TrFE) thin film capacitor for non-volatile memory applications with large polarization values but with lower voltage operation.

Another objective of the present invention is to fabricate a fatigue free P(VDF-TrFE) thin film capacitor for non-volatile memory applications with best piezoelectric properties.

Another object of the present invention is to provide P(VDF-TrFE) films that can be used for ferro, piezo and pyro electric devices.

### SUMMARY OF THE INVENTION

An aspect of the present invention provides a process for fabricating poly(vinylidenedifluoride-trifluoroethylene) [P(VDF-TrFE)] polymer films comprising steps of:
a. preparing P(VDF-TrFE) solution in methylethylketone (MEK) and dimethyl sulfoxide (DMSO) co-solvent mixture,
b. coating the solution obtained in step (a) on substrate to form P(VDF-TrFE) films, followed by annealing the films at a temperature between 138-142° C., and
c. quenching the solution in ice water,
   wherein co-solvent mixture DMSO and MEK are present in a ratio ranging from 1:1 to 1:2.

Another aspect of the present invention provides a P(VDF-TrFE) polymer film prepared by the present process that essentially comprises of co-solvent DMSO and MEK for being used in non-volatile memory integrated devices, sensors and actuators.

### BRIEF DESCRIPTION OF ACCOMPANYING DRAWINGS

FIG. 1 illustrates the structure of the PVDF-TrFE based non-volatile memory integrated device Structure FIG. 2(a) illustrates comparative AFM images of annealed P(VDF-TrFE) films with THF (Rᵣₘₛ=5.2 nm); FIG. 2(b) illustrates comparative AFM images of annealed P(VDF-TrFE) films with MEK (Rᵣₘₛ=5.8 nm); FIG. 2(c) illustrates comparative AFM images of annealed P(VDF-TrFE) films with Cyclohexanone (Rᵣₘₛ=6.3 nm); and FIG. 2(d) illustrates comparative AFM images of annealed P(VDF-TrFE) films with DMSO (Rᵣₘₛ=7.2 nm).

FIG. 3 (a) illustrates graphical representation of Polarization vs electric field curve; FIG. 3 (b) illustrates graphical representation of breakdown strength for different solution of annealed P(VDF-TrFE) with ozone treated ITO.

FIG. 4 illustrates graphical representation of fatigue behaviour of annealed P(VDF-TrFE) films on ozone treated ITO with different solvents.

FIG. 5 (a) illustrates comparative optical images of the films with (DMSO:MEK, 1:0); FIG. 5 (b) illustrates comparative optical images of the films with (DMSO:MEK, 2:1); FIG. 5 (c) illustrates comparative optical images of the films with (DMSO:MEK, 1:1); and FIG. 5 (d) illustrates comparative optical images of the films with (DMSO:MEK, 1:2).

FIG. 6 illustrates ferroelectric curve of DMSO-MEK co-solvent at different amounts of MEK at 100 Hz

FIG. 7 (a) illustrates graphical representation of remnant switchable polarization; FIG. 7 (b) illustrates graphical representation of non-switchable total polarization of P(VDF-TrFE) films derived from different MEK content in solvent.

FIG. 8(a) illustrates graphical representation of fatigue endurance of P(VDF-TrFE) films derived from co-solvent (DMSO:MEK: 1:2); FIG. 8(b) illustrates graphical representation of breakdown strength of co-solvent derived films.

FIG. 9 illustrates ferroelectric curve of DMSO-MEK co-solvent at different temperatures at 100 Hz

FIG. 10 (a) illustrates graphical representation of polarization and displacement vs electric field curve for slowly cooled films fabricated from MEK and Ice water quenched films fabricated from; FIG. 10 (b) illustrates graphical representation of polarization and displacement vs electric field curve for MEK; FIG. 10 (c) illustrates graphical representation of polarization and displacement vs electric field curve for MEK:DMSO (1:1); and FIG. 10 (d) illustrates graphical representation of polarization and displacement vs electric field curve for DMSO.

FIG. 11 illustrates graphical measurement for the pyroelectric coefficient of the P(VDF-TrFE) films derived from co-solvent (DMSO:MEK: 1:1).

### DETAILED DESCRIPTION OF THE INVENTION

The following description with reference to the accompanying drawings is provided to assist in a comprehensive understanding of exemplary embodiments of the invention. It includes various specific details to assist in that understanding but these are to be regarded as merely exemplary.

Accordingly, those of ordinary skill in the art will recognize that various changes and modifications of the embodiments described herein can be made without departing from the scope of the invention. In addition, descriptions of well-known functions and constructions are omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention are provided for illustration purpose only and not for the purpose of limiting the invention as defined by the appended claims and their equivalents.

It is to be understood that the singular forms “a,” “an,” and “the” include plural referents unless the context clearly dictates otherwise.

Features that are described and/or illustrated with respect to one embodiment may be used in the same way or in a similar way in one or more other embodiments and/or in combination with or instead of the features of the other embodiments.

It should be emphasized that the term “comprises/comprising” when used in this specification is taken to specify the presence of stated features, integers, steps or components but does not preclude the presence or addition of one or more other features, integers, steps, components or groups thereof.

The term “cost-efficient” as used in the specification refers to the cost of the fabrication which requires neither addition of foreign materials nor any expensive machine for manufacturing.

The term “simple process” as used in the specification refers to a process which does not require addition of foreign materials or any cumbersome process like reactive ion etching.

The term “high/superior fatigue endurance” as used in the specification refers to no degradation in remnant polarization on application of electric field cycles in number of at least 10⁸.

The term “low voltage operation” as used in the specification refers to a memory that can be operated with 10-15V.

The term “dielectric breakdown strength” as used in the specification refers to the maximum electric field that a dielectric material can withstand without experiencing failure of its insulating properties.

The term “superior crystallinity” as used in the specification implies to higher degree of ordering of polymer chains.

The term “higher polarization” as used in the specification refers to large remnant and saturation polarisation (˜10 μC/cm²).

The term “AFM images” as used in the specification refers to Atomic force microscopy images.

The term “ferroelectric” as used in the specification refers to a material that exhibits spontaneous electric polarization, which can also be reversed by the application of an external electric field.

The term “piezoelectric” as used in the specification refers to a material that exhibits charge, and hence, an electrical potential across the material in response to mechanical stress.

The term “pyro-electric” as used in the specification refers to a material that exhibits an electrical potential across it when subjected to a temperature change.

The term “ITO” as used in the specification is an abbreviation for Indium tin oxide.

The term “PET substrates” as used in the specification refers to thin (10-125 microns) polyethylene terephthalate films.

The term “non-switchable polarization” as used in the specification broadly refers to total polarization−remnant polarization=non-switchable polarization. Non-switchable polarization could originate due to defects in the films and/or accessories (wires etc.) used for the ferroelectric measurement.

The present invention relates to a cost-effective and simple process to fabricate P(VDF-TrFE) based memory capacitors with low voltage operation and higher fatigue endurance with large polarization values, made using methyl ethyl ketone (MEK) and dimethyl sulfoxide (DMSO) as a co-solvent.

P(VDF-TrFE) thin films as known in the prior arts were made by spin/dip coating technique using solution processing from a variety of solvents individually and not their combinations. Use of those individual solvents produced devices with certain limitations such as the resulting devices either had poor surface or poor fatigue resistance or operated at higher voltages or higher electrical leakage.

Thus, in present invention the inventors had explored the properties of the solvents and have found the improvement of P(VDF-TrFE) films can be achieved by using two solvents together, mixed in appropriate proportions. Therefore, the present invention provides a process for fabricating P(VDF-TrFE) films using a mixture of two solvents in specific proportions to tailor specific characteristics of those solutions with respect to surface tension. According to the invention the two solvents DMSO:MEK can be present in a ratio ranging from 1:1 to 1:2 providing excellent fatigue behaviour, It has been observed that if MEK contribution is greater than half in the co-solvent mixture, the P(VDF-TrFE) films formed were uniform, easily spreadable onto ITO and the wavy nature of the films almost disappeared. Particularly, it was found that when the solvent MEK is present in an amount of 50-70% of the co-solvent mixture with DMSO, an improved fatigue endurance and thermal stability of the P(VDF-TrFE) film was achieved.

Thus in an important aspect of the present invention, by using a co-solvent of MEK and DMSO in defined proportions the best performance of both solvents can be achieved together, i.e. low roughness and uniform films with good breakdown strength by MEK and large polarization and low voltage operating device by the virtue of DMSO.

In a specific embodiment of the present invention, a process for fabricating poly(vinylidenedifluoride-trifluoroethylene) [P(VDF-TrFE)] polymer films is provided comprising steps of preparing P(VDF-TrFE) solution in methylethylketone (MEK) and dimethyl sulfoxide (DMSO) co-solvent mixture, and spin coating the solution obtained in step (a) on substrate to form P(VDF-TrFE) films, followed by annealing and quenching. The two solvents DMSO and MEK are present in a ratio ranging from 1:1 to 1:2.

In another aspect of the present invention, specific composition of solvent mixtures of MEK and DMSO allows for improved crystallographic alignment of the P(VDF-TrFE) film on a substrate from the perspective of polar axis and which also leads to excellent electrical fatigue endurance of P(VDF-TrFE). The measured values meet the functional requirements of commercial products.

In another aspect of the present invention, the use of co-solvent of DMSO and MEK in specific proportions is to fabricate fatigue free P(VDF-TrFE) thin film capacitors for nonvolatile memory applications results into very little non-switchable polarization, lower voltage operation and low level of chemical defects.

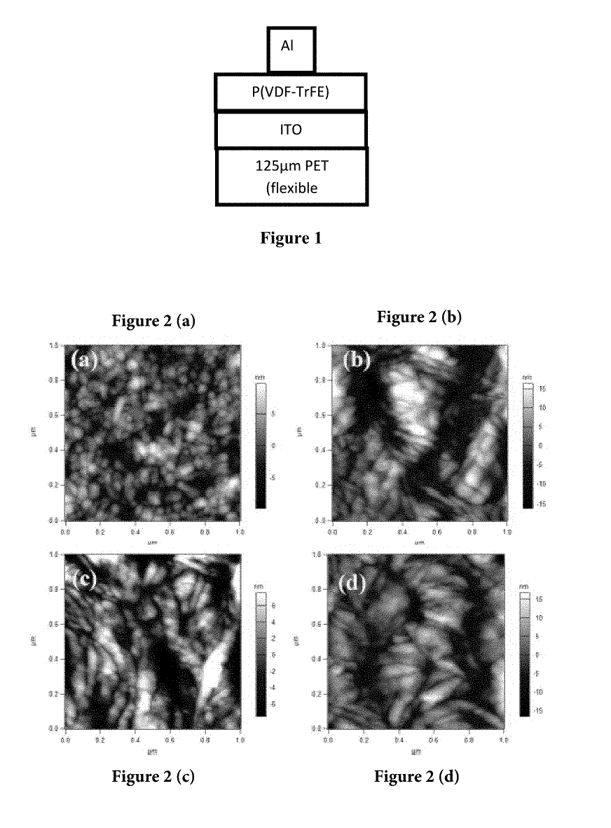

In an aspect of the present invention, the experiments were conducted on ITO (Indium tin oxide) coated PET (polyethylene terephthalate) substrates. P(VDF-TrFE) solutions were prepared in solvents with different dipole moments (μ) such as tetrahydrofuran (THF μ: 1.63D, B.P.:65° C.), Methyl ethyl ketone (MEK μ: 2.76D, B.P.: 80° C.), cyclohexanone (μ: 2.87D, B.P.: 155° C.) and dimethyl sulfoxide (DMSO μ: 3.96D, B.P.: 189° C.). Concentration of P(VDF-TrFE) was maintained at 25 mg/ml in each solvent. Films of P(VDF-TrFE) were spin coated followed by annealing. The films were subsequently quenched in ice water. Top electrodes of 1 mm diameter were fabricated by thermally evaporating Al through a metal mask for making electrical measurements. The arrangement of such device has been portrayed in accompanying FIG. 1.

For better adherence of the films on ITO substrates films were fabricated by using above solvents on UV ozone treated ITO substrates to investigate the effects of the solvents only on the P(VDF-TrFE) thin films. In another aspect of the present invention, the above mentioned experiment can be conducted on substrates selected from a polymer or polyester such as polyethylene terephthalate (PET), polyimide, polyethylene naphthalate (PEN), polyetherimide (PEI) or flexible metal foils and textiles, which can be coated with electrically conducting metal oxides such as indium tin oxide (ITO), fluorine doped tin oxide (FTO), zinc oxide or any other material suitable as electrode.

Further, in another aspect of the present invention the polymer P(VDF-TrFE) films produced by the present process are quenched in ice water after annealing.

Another important aspect of the present invention is to provide a simple and cost-effective process to fabricate P(VDF-TrFE) films. The present process does not involve any reactive metals or ion or any other ingredients and even does not need changing the electrode or adding of any other interfaces, thus making the process cost efficient and simple. Also, the present process can be employed in making non-volatile memory integrated devices.

Another aspect of the present invention is to provide a process for fabricating P(VDF-TrFE) films which exhibit 100% retention of remnant polarization after 10⁸ bipolar electrical switching cycles.

In yet another aspect of the present invention, the P(VDF-TrFE) thin film capacitors devices are thermally stable up to 100-122° C., thus making them ideal candidates for applications requiring high operating temperatures.

Furthermore, another important aspect of the present invention is to provide a process for fabricating P(VDF-TrFE) films which leads to excellent fatigue improvement without any compromise in ferroelectric polarization, dielectric constant, and thermal stability whilst reducing the operating voltage. Such improved P(VDF-TrFE) based capacitors can be used for non-volatile memory, piezo and pyro electric devices. Even the piezoelectric coefficient demonstrated in the present invention is the best achieved so far in this field of art.

Further, in an aspect of the present invention the large polarization and dielectric breakdown strength of ferroelectric films enable them for application in large D.C. bias which can further increase the piezoelectric properties of P(VDF-TrFE) films.

The invention is now illustrated by way of non-limiting examples. The examples are intended to be purely exemplary of the invention, should therefore not be considered to limit the invention in any way.

### EXAMPLES

### Example 1: Experimental Set Up

ITO coated PET substrates were cleaned by ultrasonicating in acetone, isopropyl alcohol (IPA) and deionized water for 10 min in each solvent. P(VDF-TrFE) solutions were prepared in solvents with different dipole moments (μ):tetrahydrofuran (THF μ: 1.63D, B.P.:65° C.), Methyl ethyl ketone (MEK μ: 2.76D, B.P.: 80° C.), cyclohexanone (μ: 2.87D, B.P.:155° C.) and dimethyl sulfoxide (DMSO μ: 3.96D, B.P.: 189° C.). Concentration of P(VDF-TrFE) was maintained at 25 mg/ml in each solvent. Films of P(VDF-TrFE) were spin coated at 3000 rpm for one minute followed by annealing at a temperature ranging from 138-142° C. for 1 hour. The films were subsequently quenched in ice water. Top electrodes of 1 mm diameter were fabricated by thermally evaporating Al through a metal mask for making electrical measurements. The arrangement of such device has been portrayed in accompanying FIG. 1. For better adherence of the films on ITO substrates films were fabricated by using above solvents on UV ozone treated ITO substrates to investigate the effects of the solvents on the P(VDF-TrFE) thin films. The duration of ozone treatment was 30 minutes. P(VDF-TrFE) solution made using different solvents with concentration of P(VDF-TrFE) being 25 mg/ml in each case was spin coated on these substrates.

### Example 2: Comparative AFM Images

The P(VDF-TrFE) films produced by casting with different solvents in an experimental set up as mentioned in example 1 were studied under AFM. As illustrated in accompanying FIG. 5, all films showed good thickness uniformity, except the one which was casted from DMSO solvent alone. The DMSO casted P(VDF-TrFE) film had wide variation in thickness i.e. 195±30 nm. AFM images (as illustrated in FIG. 2) also showed an increase in the grain size with increasing boiling point and dipole moment of the solvent: THF derived films showed very tiny spherical grains, MEK and cyclohexanone derived films showed moderate size grains and DMSO derived films exhibited needle shaped featured. The grain size increased further on annealing the films.

### Example 3: Ferroelectric Measurements Conducted on P(VDF-TrFE) Thin Film Capacitors Fabricated on Ozone Treated ITO from Different Solvents

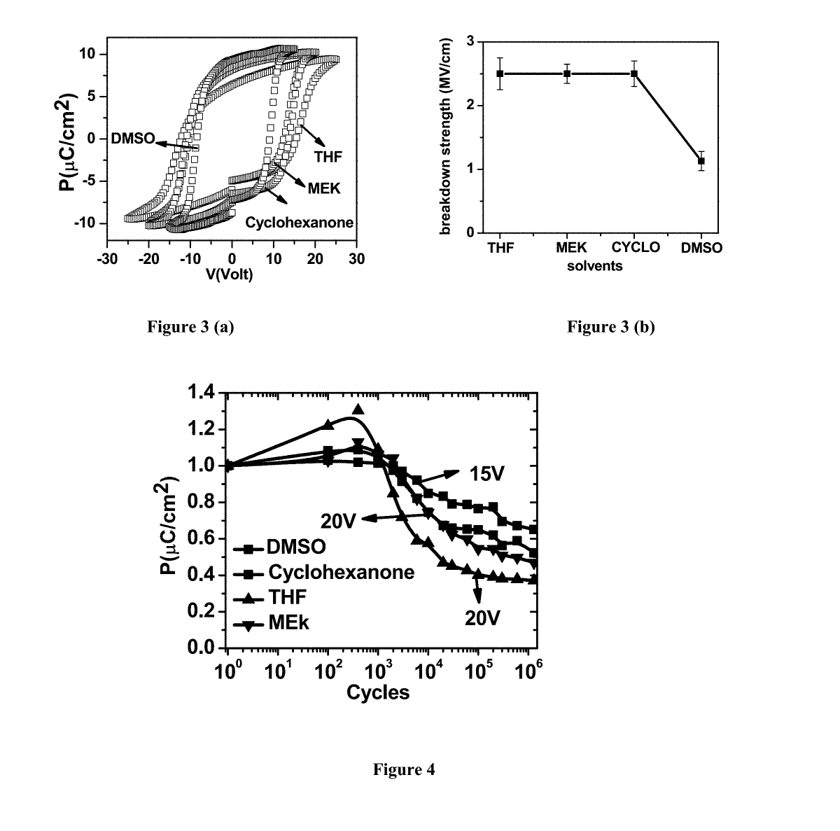

FIG. 3 illustrates the results of ferroelectric measurements conducted on P(VDF-TrFE) thin film capacitors fabricated on ozone treated ITO from different solvents (as mentioned in the experimental set up of example 1 above). FIG. 3(a) illustrates well saturated ferroelectric hysteresis loops of the P(VDF-TrFE) thin films in all case but with differences in the polarization (Pₛ and Pᵣ) and coercive field values. Devices of DMSO derived films switch even at 10 V suggesting their applicability for low voltage memory devices and highlight the importance of using highly polar solvents like DMSO and the surface treatment. Another important parameter, breakdown strength of the ferroelectric films derived from different solvents is depicted in FIG. 3(b). All films have similar breakdown strength except DMSO. Low breakdown strength of DMSO films could be due to wavy nature of the films which can inhibit poor electrode/film interphase. In the present invention, higher concentrations of P(VDF-TrFE) in DMSO solution was also tried but still no success was achieved in forming uniform films with DMSO.

### Example 4: Fatigue Behaviour of Annealed P(VDF-TrFE) Films on Ozone Treated ITO with Different Solvents

In order to assess the performance of the P(VDF-TrFE) films from the perspective of memory applications, bipolar electrical fatigue measurements on the devices were conducted. The results as depicted in FIG. 4 shows interesting trend. In the THF devices, the polarization starts dropping at ca. 400 cycles and then drops suddenly to 30% of the initial value. In contrast, DMSO-devices, electrical fatigue is slow and even after 10⁶ cycles, the drop in polarization is about 35% whilst the performance of MEK and cyclohexanone devices is intermediate. It was observed that in all the devices, the polarization increases first followed by a decrease due to fatigue. This enhancement has been attributed to field induced crystallinity and the enhancement was larger if the original polarization (Pᵣ(0)) is smaller. It has been further observed in the present invention that the enhancement is more in THF-devices and least in the case of DMSO-devices, corroborating the reports in the literature. In DMSO-devices, since the polymer chains are better extended, they have lower density of gauche defects e.g. chain entanglement. Hence, the effect of crystalline rearrangement is minimal after the application of cyclic electric field. Due to low defects density and superior crystallinity, the DMSO devices also show least degradation. But as the applied voltage was increased to 20V, close to the breakdown voltage, DMSO derived devices have poor fatigue endurance similar to the MEK and cyclohexanone derived devices. Table 1 below summarizes the results obtained.

TABLE 1
Summary of ferro-electric and film properties.
All films are 200 nm thick.

| Solvent [symbol] | | | cyclo- | |
|---|---|---|---|---|
| properties [symbol] | THF | MEK | hexanone | DMSO |
| Pᵣ(μC/cm²) | 6.5 ± .3 | 7.6 ± .2 | 7.8 ± .3 | 9 ± .1 |
| Ec (MV/cm) | 0.68 ± .05 | 0.55 ± .03 | 0.61 ± .03 | 0.40 ± .04 |
| Breakdown strength | 2.6 ± .13 | 2.6 ± .1 | 2.6 ± .15 | 1.12 ± .2 |
| (MV/cm) | | | | |
| Roughness (nm) | 5.2 | 5.8 | 6.3 | 7.2 |
| Polarization | 35% | 50% | 52% | 52% and |
| retention after | | | | 65% at 15 V |
| 10\hat{ }6 cycles (at 20 V) | | | | |

From the above data, it is evident that the use of DMSO solvent leads to P(VDF-TrFE) films with superior polarization and lower coercivity, both desirable for memory application, but the smaller breakdown strength and less uniform film thickness constraints it's usability.

Hence, after investigating effects of various solvents in forming P(VDF-TrFE) it became important to find an approach to improve the breakdown strength and fatigue endurance of such DMSO derived P(VDF-TrFE) films.

### Example 5: Electrical Fatigue Endurance and Breakdown Strength of P(VDF-TrFE) Films by Co-Solvent of DMSO and MEK

### Example 5(a): Uniform Thickness Achieved by Using DMSO and MEK Co-Solvents

FIG. 5(a) illustrates that DMSO derived P(VDF-TrFE) films exhibited a wavy morphology with larger thickness variations due to DMSO's large surface tension (42.9 mN/m). Hence, to fabricate smoother thin film of PVDF-TrFE on ITO, a new approach was introduced by preparing the solvent by mixing MEK and DMSO in various proportions. The idea was to optimize the surface morphology whilst not compromising on the ferroelectric behaviour substantially. Since MEK has lower surface tension of 24.6 mN/m, its addition to DMSO reduce the overall surface tension. Also, MEK addition to DMSO also leads to immediate vaporization after the film deposition. Hence, PVDF-TrFE solution (25 mg/ml) was prepared with different ratios of DMSO and MEK (DMSO:MEK (v/v)=2:1, 1:1 and 1:2) and spin coated the solutions on the ozone treated ITO surface. It was observed that when MEK contribution is greater than half in the solution, the films formed were uniform and easily spreadable onto ITO and wavy nature of the films almost disappeared [FIG. 5(d)].

### Example 5(b): Ferroelectric Measurement of DMSO-MEK Co-Solvent at Different Amount of MEK at 100 Hz

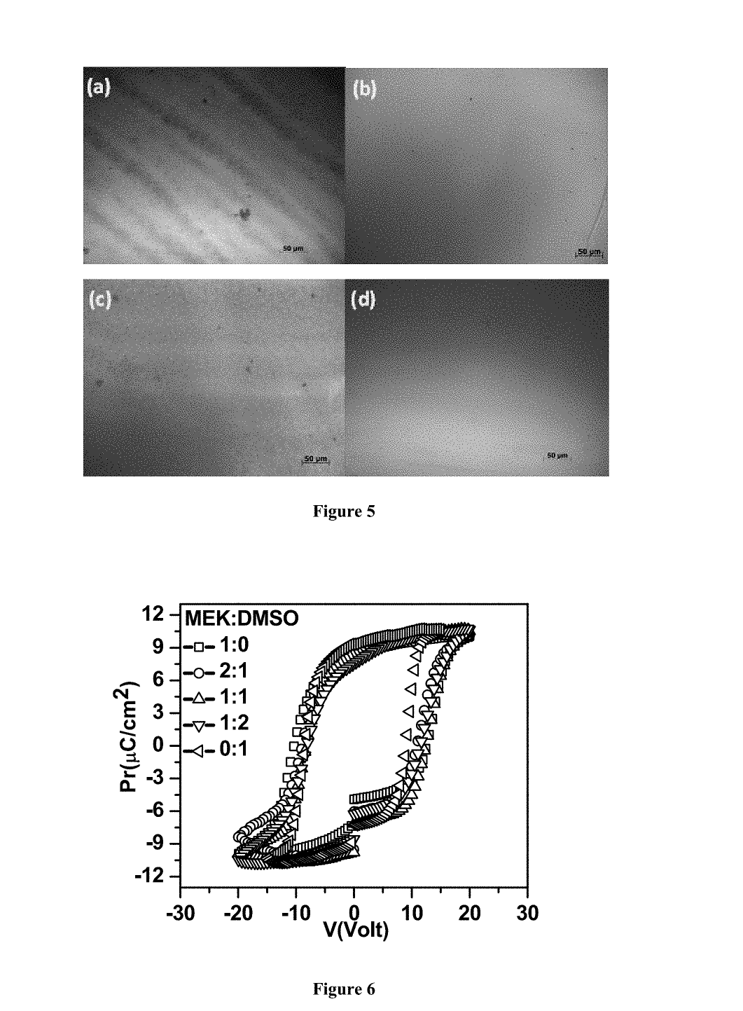

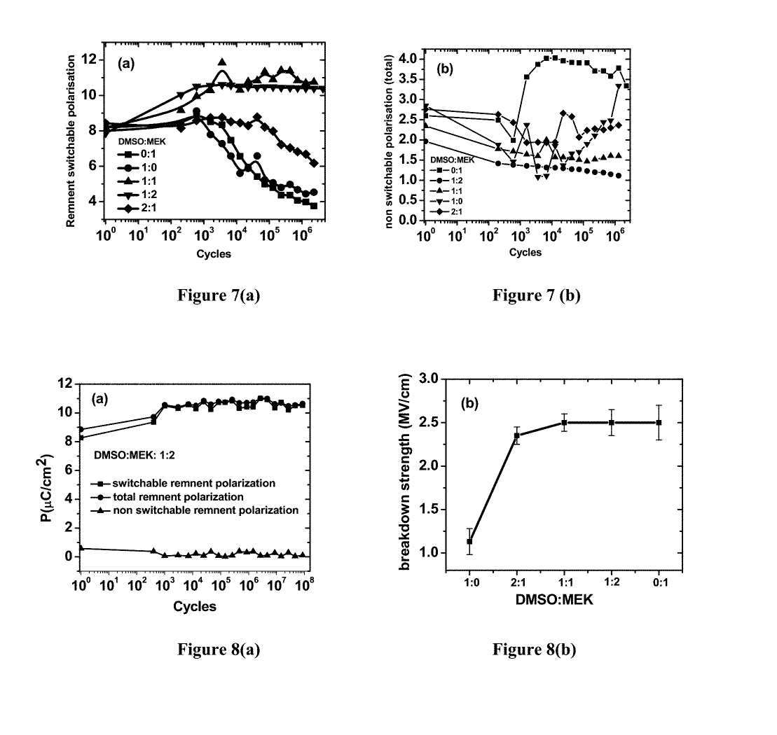

FIG. 6 represents polarization data of PVDF-TrFE film mediated capacitors made from the co-solvents DMSO and MEK. No major changes were observed in Pr values, while coercive voltage values lie between the value of pure DMSO and MEK. Most dramatic change was observed in the fatigue endurance of co-solvent samples [as shown in FIGS. 7(a) and 7(b)]. The capacitors made using such co-solvent approach are fatigue free when MEK concentration is either equal or greater than half. With increase in the numbers of programming cycles, the films formed by co-solvents DMSO:MEK in a ratio of 1:2 showed no degradation up to 10⁸ programming cycles [as shown in FIG. 8(a)]. Such improved fatigue behaviour is perhaps due to improved bond strength which does not lead to chemical dissociation of P(VDF-TrFE) and excellent film formation of P(VDF-TrFE) films. Another key observation is that the co-solvent samples made using a DMSO:MEK ratio of 1:1 and 1:2 shows much superior fatigue endurance as well as reduced non-switchable polarization in comparison to films made using either pure DMSO or pure MEK. FIG. 8(b) illustrates improved breakdown strength of co-solvent derived devices.

Furthermore, the graphical data as shown in FIGS. 7(a) and 7(b) clearly demonstrates that degradation in the remnant switchable polarization started when the P(VDF-TrFE) films are formed by the co-solvents DMSO and MEK in a ratio of 2:1. Additionally, it is also evident from the graph in FIG. 8(b) that when the co-solvent DMSO:MEK ratio is 2:1, the breakdown strength of the said co-solvent derived device is comparatively lower to those formed by the co-solvents DMSO and MEK in ratios 1:1 and 1:2.

Therefore, it is evident from the above that by using a co-solvent of MEK and DMSO in a ratio ranging between 1:1 to 1:2, the best performances of both solvents were utilized, i.e. low roughness and uniform films with good breakdown strength by MEK and large polarization and low voltage operating device by the virtue of DMSO.

### Example 6: Thermal Stability of P(VDF-TrFE) Films Formed by Co-Solvent of DMSO and MEK

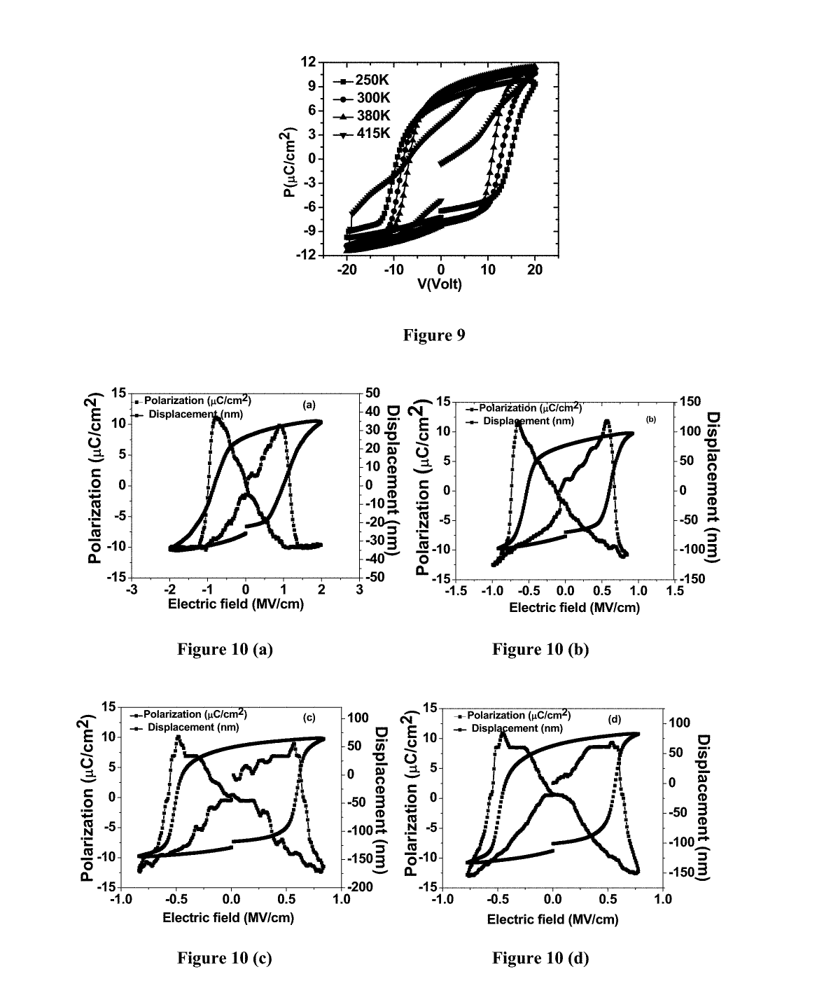

FIG. 9 represents excellent thermal stability of the P(VDF-TrFE) films formed by using the co-solvents DMSO and MEK. Such P(VDF-TrFE) film devices showed superior polarization value without any sign of leaky behaviour. After the curie point of the films (˜405K) devices showed reduced ferroelectric behaviour. The samples were fabricated using a DMSO:MEK ratio of 1:2. This data above shows that that at the ratio of DMSO:MEK at 1:2, the P(VDF-TrFE) film devices exhibited superior fatigue endurance as well as improved thermal stability.

### Example 7: Comparative Analysis Between the Performance of the P(VDF-TrFE) Films Formed by the Present Process and that of the Films Formed in the Prior Arts

In the present invention the P(VDF-TrFE) films are formed by using co-solvents DMSO and MEK in specific proportions as mentioned in example 5. The comparison has been made against the two best P(VDF-TrFE) films reported in the art as below,

a) M. A. Khan et al.: Adv. Funct. Mater., 24, 1372 (2014) that discloses high-performance polymer memory which is fabricated using blends of ferroelectric poly(vinylidene-fluoride-trifluoroethylene) (P(VDF-TrFE)) and highly insulating poly(p-phenylene oxide) (PPO) along with enhanced thermal stability, excellent fatigue endurance (80% retention after 10⁶ cycles at 1 KHz) and high dielectric breakdown fields (≈360 MV/m).

b) D. Zhao et al.: Scientific reports, 4, 5075 (2014) which reveals that a fatigue-free capacitor can be realized by using a polymer electrode (PEDOT:PSS) and a triangular waveform with waiting time of 10 seconds.

The comparative performance analysis of the films has been summarized in Table 2.

TABLE 2
Performance comparison of DMSO and MEK
co-solvent mediated (P(VDF-TrFE) of
the present invention with the two best previously reported.

| | | | | | Fatigue |
|---|---|---|---|---|---|
| | | | | | endurance |
| | | | | | (triangular |
| | | | | | waveform |
| | | | Rough- | Thermal | at 100 Hz |
| Preparation | Pr | Ec | ness | stability | after 10⁶ |
| method | (μc/cm²) | (MV/cm) | (nm) | (K) | cycles) |
| Addition of | ≈4.9 | .67 ± 0.05 | ≈5 | ≈353 | 40% reduction |
| 8 wt % PPO in | | | | | in Polarization |
| films (ref. “a” | | | | | |
| above) | | | | | |
| With | — | — | — | — | 20% reduction |
| PEDOT:PSS | | | | | in Polarization |
| Electrodes | | | | | |
| (ref “b” | | | | | |
| above) | | | | | |
| PRESENT | ≈8-8.9 | .52 ± .02 | 6.2 | ≈395 | 25% increment |
| INVENTION | | | | | in Polarization |

### Example 8: Piezoelectric Properties of P(VDF-TrFE) Films Formed by Co-Solvent of DMSO and MEK

P(VDF-TrFE) being ferroelectric is also piezoelectric and pyroelectric. Piezoelectric films are used in electronic devices like sensors and actuators. Piezoelectricity is used in applications such as the production and detection of sound, high voltages and electronic frequency generation. Free standing thick films from solutions with MEK, DMSO and MEK:DMSO (1:1) as solvents were selected. All films were annealed at 134-142° C. followed by ice quenching. Further, conventionally used film from MEK was also made which is slowly cooled on the hotplate for the comparison. FIG. 10 represents the polarization and displacement curves of these films. FIG. 10 shows that DMSO derived films give superior ferroelectric loops at lowest electric field just like the thin P(VDF-TrFE) films. Improved d₃₃ values were observed in ice quenched P(VDF-TrFE) films as compared to the conventionally used slowly cooled films. These values further increased when high dipole moment solvent was used. Films derived by co-solvent of MEK:DMSO (1:1) gives d₃₃ values comparable to the DMSO derived films which further advocates the utility of co-solvent derived films in not only the memory applications but also for sensors and actuators. Table 3 (as below) summarizes the piezoelectric properties of P(VDF-TrFE) films of the present invention.

TABLE 3
d₃₃ values of freestanding films with different solvent;

| | | | | Applied | Thick- |
|---|---|---|---|---|---|
| | Preparation | d₃₃₊ | d₃₃₋ | electric | ness |
| solvent | method | (pm/V) | (pm/V) | field | (μm) |
| MEK | Slowly cooled | −13 | 12 | 2 | 11 |
| | (cooling | | | MV/cm | |
| | time ≈30 minutes) | | | | |
| | after annealing | | | | |
| MEK | Ice water quenched | −37 | 40 | 0.9 | 27 |
| | after annealing | | | MV/cm | |
| MEK:DMSO | Ice water quenched | −60 | 51 | 0.85 | 32 |
| (1:1) | after annealing | | | MV/cm | |
| DMSO | Ice water quenched | −63 | 61 | 0.8 | 32 |
| | after annealing | | | MV/cm | |

In the following Table 4, a comparative analysis has been made between the piezoelectric co-efficient achieved by the P(VDF-TrFE) films formed by the present process and that of the films formed in the previously reported prior arts.

TABLE 4
Comparative data on reported d₃₃ coefficient of
P(VDF-TrFE) films with prior arts.

| Preparation method | Effective d₃₃ (pm/V) | Reference |
|---|---|---|
| Spin coating of | −10.7 | Hong-Jie Tseng et.al: |
| P(VDF-TrFE) on | | Sensors, 13 (11) (2013) |
| steel substrate | | |
| Langmuir-Blodgett | −20 ± 2 | A. V. Bune et.al: Journal |
| deposition of | | of Applied Physics, 85, |
| P(VDF-TrFE) on glass | | number 11, 7869 (1999) |
| Not defined | −40 ± 2 | Yoon-young Choi et.al.: |
| | | Scientific Reports, |
| | | Article no. 10728 (2015) |
| P(VDf-TrFE) with | −22 | Rachid Hazi et.al, IEEE |
| 7 wt % alumina | | transactions on |
| | | ultrasonics, |
| | | ferroelectrics, and |
| | | frequency control, 59(1), |
| | | 163-7. (2012) |
| Piezotech S.A.S. | −20 ± 10% | P(VDF-TrFE) |
| Arkema France | | COPOLYMER 70/30 |
| | | FILM −20 μm (±10%) |
| | | THICKNESS from |
| | | Piezotech S.A.S. Arkema |
| | | France |

Thus, based on the above data in table 3 and table 4, it has been observed that these P(VDF-TrFE) films formed by the present process involving co-solvents DMSO and MEK provides better piezo-electric co-efficient (˜60 pm/V) from the prior art.

### Example 9: Pyroelectric Properties of P(VDF-TrFE) Films Formed by Co-Solvent of DMSO and MEK

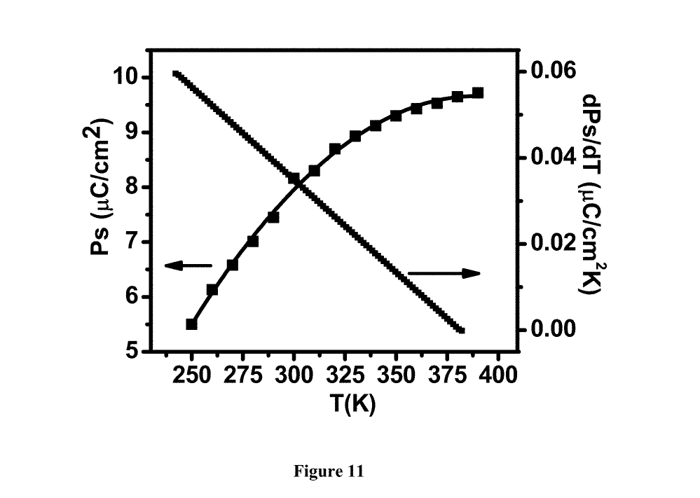

P(VDF-TrFE) being ferro- and piezo-electric is pyro-electric as well. Furthermore, the experimental data in above example 6 demonstrating thermal stability of the present P(VDF-TrFE) films formed by co-solvent of DMSO and MEK, confirms pyro-electric effect. Additionally, FIG. 11 represents a saturation polarization (Ps) versus temperature (T) plot (blue curve) at constant electric field (and stress), which shows that magnitude of Ps increases as T increases, hence the P(VDF-TrFE) films formed by present process is pyro-electric. This data is for DMSO:MEK at 1:1.

Since, pyroelectric coefficient (p) is defined as p=dPs/dT at constant electric field and stress [as defined in the prior art Bowen C. R. et al.: Energy Environ. Sci., 7, 3836 (2014)]., FIG. 11 shows, the value for dPs/dT where pyroelectric coefficient has been calculated from the plot for the DMSO-MEK co-solvent derived P(VDF-TrFE) films and is found to be approximately 384(ρCm⁻²K⁻¹). Such value is ten times greater than previously reported pyroelectric co-efficient i.e. −35 (μCm⁻²K⁻¹) in the prior art [Bowen C. R. et al.: Energy Environ. Sci., 7, 3836 (2014)]. Therefore, it shows that pyroelectric coefficient for the present P(VDF-TrFE) films formed by co-solvent of DMSO and MEK is high.

1. A process for fabricating poly(vinylidenedifluoride-trifluoroethylene) [P(VDF-TrFE)] polymer films comprising steps of:
a. preparing P(VDF-TrFE) solution in methylethylketone (MEK) and dimethyl sulfoxide (DMSO) co-solvent mixture,
b. coating the solution obtained in step (a) on substrate to form P(VDF-TrFE) films, followed by annealing the films at a temperature between 138-142° C., and
c. quenching the solution in ice water,
wherein co-solvent mixture DMSO and MEK are present in a ratio ranging from 1:1 to 1:2.

2. The process as claimed in claim 1, wherein the co-solvent mixture DMSO and MEK are present in a ratio of 1:2.

3. The process as claimed in claim 1, wherein the substrate is selected from group consisting of polyethylene terephthalate (PET), polyimide, polyethylene naphthalate (PEN), polyetherimide (PEI), flexible metal foils, textiles.

4. The process as claimed in claim 1, wherein the substrate is further treated with UV ozone.

5. The process as claimed in claim 1, wherein concentration of P(VDF-TrFE) in co-solvent mixture is maintained at 25 mg/ml.

6. The process as claimed in claim 1, wherein P(VDF-TrFE) thin films formed have a low roughness of 6.2-7 nm.

7. The process as claimed in claim 1, wherein the P(VDF-TrFE) thin films formed exhibit polarization (Pr) values ranging from 8.9 to 9.0 μc/cm².

8. The process as claimed in claim 1, wherein the P(VDF-TrFE) thin films formed exhibit 100% retention of remnant polarization after 10⁸ bipolar electrical switching cycles.

9. The process as claimed in claim 1, wherein P(VDF-TrFE) thin films formed are thermally stable up to 100° C.-122° C.

10. The process as claimed in claim 1, wherein P(VDF-TrFE) free standing thick films exhibit piezoelectric coefficient (d33 value) of −60 pm/V.

11. The process as claimed in claim 9, wherein P(VDF-TrFE) films exhibit pyroelectric coefficient of 384 (μCm⁻²K⁻¹).

12. The process as claimed in claim 1, wherein said process is carried out having non switchable polarization and low voltage.

13. The process as claimed in claim 1, wherein said process is having dielectric breakdown field of 2.35-2.65 MV/cm.

14. The process as claimed in claim 12, wherein said low voltage ranges from 10V-15V.

15. A P(VDF-TrFE) polymer film prepared by the process as claimed in claim 1 comprising the co-solvent DMSO and MEK for use in non-volatile memory integrated devices, sensors and actuators.
